(19) United States
(12) Patent Application Publication
(10) Pub. No.: US 2004/0160895 A1
(43) Pub. Date: Aug. 19, 2004

(54) FAILURE NOTIFICATION METHOD AND SYSTEM IN AN ETHERNET DOMAIN

(75) Inventors: Stephen L. Holmgren, Little Silver, NJ (US); David Kinsky, High Bridge, NJ (US); Mateusz W. Szela, Hillsborough, NJ (US)

Correspondence Address: AT&T CORP., P.O. BOX 4110, MIDDLETOWN, NJ, 07748, US

(73) Assignee: AT&T CORP., New York, NY (US)

(21) Appl. No.: 10/248,761

(22) Filed: Feb. 14, 2003

(51) Int. Cl. G01R 31/08

(52) U.S. Cl. 370/223; 370/216

(57) ABSTRACT

The present invention is directed to novel mechanisms for failure notification in an Ethernet domain that can span one or more Ethernet service providers.

### BACKGROUND OF INVENTION

The present invention relates to Ethernet networks and, more particularly, to operations, administration, management in an Ethernet-based network.

There exists a large embedded base of Local Area Networks (LANs) based on an Ethernet architecture, i.e., the IEEE 802.3 carrier-sense multiple access standard. See, e.g., IEEE Std. 802-1990, “IEEE Standards for Local and Metropolitan Access Networks: Overview and Architecture,” IEEE Std 802.3, “Carrier Sense Multiple Access with Collision Detection (CSMA/CD) Access Method and Physical Layer Specification” (1998Ed.). Advances in high-speed Ethernet technology have led to the development of Metropolitan Area Networks (MANs), operated and maintained by Ethernet service providers (ESPs), which offer significant cost advantages on a per port basis as compared to competing architectures. Managing customers in an Ethernet domain, however, poses serious challenges. No alert capabilities are provided for remote failures in an Ethernet domain; traditional Ethernet switches only know the status of what is immediately connected to them. Recently, the IEEE 802.3 Working Group has proposed the 802.3ah “Ethernet in the First Mile (EFM)” draft standards on utilizing Ethernet as the basis for subscriber access networks—including proposed protocol extensions to support Operations, Administration, and Maintenance (OAM).

These OAM protocol extensions, unfortunately, to the knowledge of the inventors, have only been described in point-to-point environments. The problem of managing entities in an Ethernet domain that spans one or more Ethernet service providers—and, moreover, that involves endpoints tagged (and untagged) with Virtual Local Access Network (VLAN) identifiers (e.g., utilizing IEEE 802.1Q protocol headers)—has not been addressed.

### SUMMARY OF INVENTION

The present invention is directed to novel mechanisms for failure notification in an Ethernet domain that can span one or more Ethernet service providers. Where a failure occurs on any link in an end-to-end path in the Ethernet domain, in accordance with an aspect of the invention, an attempt is made to notify the affected end stations so that appropriate re-routing may occur. A point-to-point failure notification message is utilized, where available, to alert local Ethernet nodes of the failure. A specialized virtual local area network failure notification message is also broadcast to all stations belonging to said virtual local area network and to stations that manage traffic for said virtual local area network. Which Ethernet node is responsible for transmitting the virtual local area network failure notification message will depend on where the failure occurred. Where the failure message must traverse an untagged boundary in the Ethernet domain, e.g. at links to customer routers, the virtual local area network failure message is translated into a standard protocal data unit that does not utilize the virtual local area network tagging. In accordance with another aspect of the invention, two different virtual local area network failure notification messages are provided for: an “alarm indication signal” which denotes a failure notification that propagates in the same direction as the failure and a “remote defect indicator” which denotes a return message that indicates a failure on the other path of the same link pair. Where an end station receives an virtual local area network alarm indication signal, the end station transmits a virtual local area network remote defect indicator back towards the Ethernet domain.

The present invention advantageously can provide automated failure notification in an Ethernet domain—even where the Ethernet domain spans one or more Ethernet service providers and/or involves end points that are tagged or untagged with virtual local area network protocol headers. These and other advantages of the invention will be apparent to those of ordinary skill in the art by reference to the following detailed description and the accompanying drawings.

### BRIEF DESCRIPTION OF DRAWINGS

FIG. 1 is a diagram of a network, used to illustrate an embodiment of the invention.

FIG. 2 is a diagram of the network shown in FIG. 1 providing more detail on the link pairs.

FIG. 3A, 3B, 3C, and 3D are procotol structures useful for implementing an embodiment of the invention.

FIG. 4 through FIG. 13 illustrate failure notification in light of different possible interface failures that can occur in the network shown in FIG. 2, in accordance with an embodiment of the invention.

### DETAILED DESCRIPTION

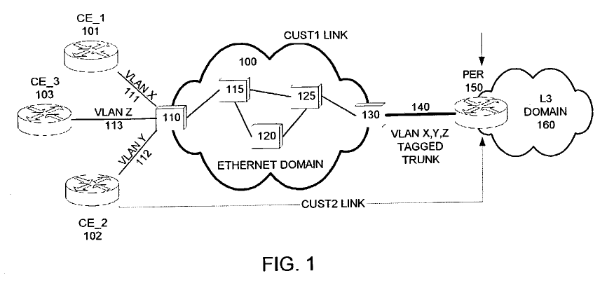

FIG. 1 is a schematic diagram of a network, used to illustrate an embodiment of the invention. In FIG. 1, an Ethernet domain 100 is shown that provides network services to a plurality of customers and/or customer sites. The Ethernet domain 100 comprises a plurality of layer two nodes, shown in FIG. 1 as Ethernet switches 110, 115, 120, 125, 130. The Ethernet domain 100 operates at layer two in the well-known seven-layer OSI model and serves to connect a plurality of customer endpoints 101, 102, 103 to a network edge node 150. The customer endpoints 101, 102, 103 and network edge node 150 are higher layer devices, illustratively and advantageously layer three routers. In FIG. 1, layer three node 150 is a provider edge router (PER) which facilitates access to a layer three domain 160, e.g. a high speed Internet Protocol packet network. Customer endpoints 101, 102, 103 can be layer three routers which aggregate traffic at a particular customer site. For illustration purposes, FIG. 1 only shows three customer endpoints 101, 102, 103 although any number of customers and customer sites may be shown connected to the Ethernet domain 100.

It is advantageous to utilize the concept of a “virtual local area network” (VLAN) as a point-to-point unique customer identifier in the Ethernet domain—similar to the concept of a permanent virtual circuit in wide area network-based protocols such as Frame Relay and ATM. See, e.g., United States Utility Patent Application, “TECHNIQUE FOR ETHERNET ACCESS TO PACKET-BASED SERVICES”, Ser. No. 09/772,360, filed on Jan. 30, 2001, and Ser. No. 10/001,545, filed on Oct. 31, 2001, the contents of which are incorporated by reference herein. For example, in FIG. 1, customer router 101 belongs to one virtual local area network, namely VLAN “X” while customer router 102 is associated with VLAN “Y” and customer router 103 is associated with VLAN “Z.” Traffic in the Ethernet domain 100 can be tagged with a VLAN identifier, in accordance with known standards for virtual bridged LANs. See, e.g., IEEEE Std 802.1Q-1998, “Virtual Bridged Local Area Networks,” Traffic between the customer routers 101, 102 and the Ethernet switch 110 at 111, 112 remains untagged. Traffic between the customer router 103 and the Ethernet switch 110 at 113 is assumed to be tagged. The provider edge router 150 has multiple sub-interfaces: one for each virtual local area network in the Ethernet domain 100. The link 140 between Ethernet switch 130 and the provider edge router 150 is an 802.1Q VLAN tagged trunk. Thus, traffic from a particular customer site can be readily sent to other sites of the same customer within the Ethernet domain 100 by appropriately setting a VLAN tag in each Ethernet frame.

The Ethernet domain 100 is not limited to a single Ethernet service provider and, for purposes of the present invention, may consist of multiple Ethernet service providers (ESPs). In such a case, the layer two device “facing” the provider edge router 150, namely switch 130 in FIG. 1, would aggregate traffic from multiple Ethernet service providers.

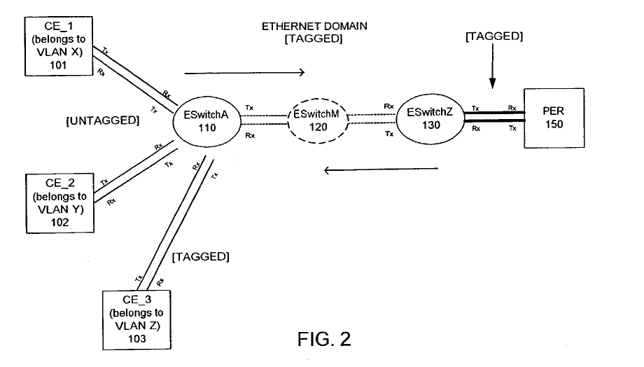

FIG. 2 is another diagram of the network shown in FIG. 1, but providing more detail on the Tx and Rx link pairs. Again, for purposes of the illustration, the link between customer router 101 and Ethernet switch “ESwitchA” 110 is untagged. Similarly, the link between customer router 102 and ESwitchA 110 is also untagged. The links between ESwitchA 110 and the other switches in the Ethernet domain—including the link to some customer routers such as 103—are tagged utilizing VLAN identifiers, namely VLAN “X” or VLAN “Y” or VLAN “Z”. The provider edge router 150 has multiple sub-interfaces, one for each VLAN, to ESwitchZ 130. The numbering in FIG. 2 corresponds to the numbering in FIG. 1, except for the node 120 labelled with dotted lines as “ESwitchM” which can represent multiple possible switches in the Ethernet domain. The invention shall be further described with reference to figures that mimic the features of FIG. 2.

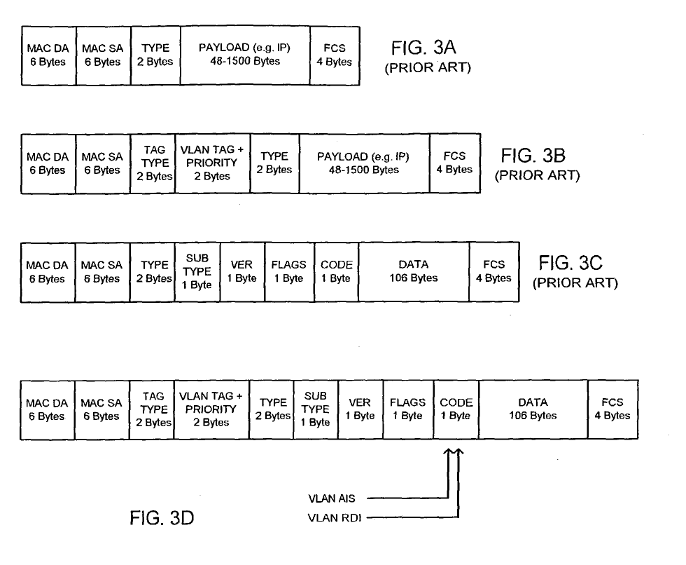

It is assumed, for illustration purposes, that the Ethernet frames follow the standard Ethernet II protocol data unit (PDU), as shown in FIG. 3A, and that the Ethernet frames, where VLAN tagging is enabled, follow the standard 802.1Q PDU, as shown in FIG. 3B. It is also assumed that the proposed 802.3ah Ethernet OAM PDU, as shown in FIG. 3C, as well as the relevant functionality in the Ethernet hardware, has been settled and adopted. The IEEE 802.3ah proposal sets forth two fault notification codes in the proposed PDU shown in FIG. 3C. They are: LOCAL FAULT and REMOTE FAULT. In accordance with an embodiment of an aspect of the invention, the protocol structures are further enhanced, as illustrated by the PDU shown in FIG. 3D. It is advantageous to define two new VLAN-based failure notifications: referred to by the inventors as (1) VLAN AIS (alarm indication signal) and (2) VLAN RDI (remote defect indicator). The failure notification would be contained in the “CODE” field of the PDU. VLAN AIS, as further illustrated below, would denote a failure notification that propagates in the same direction as the failure. VLAN RDI, as further illustrated below, would denote a return message that indicates failure on the other path of the same pair. When a VLAN AIS reaches an untagged boundary, it is envisioned that the VLAN AIS can be mapped to an 802.3ah PDU with a field “CODE”=LOCAL FAULT. Likewise, a VLAN RDI can be mapped to an 802.3ah PDU with a field “CODE”=REMOTE FAULT, as further illustrated below.

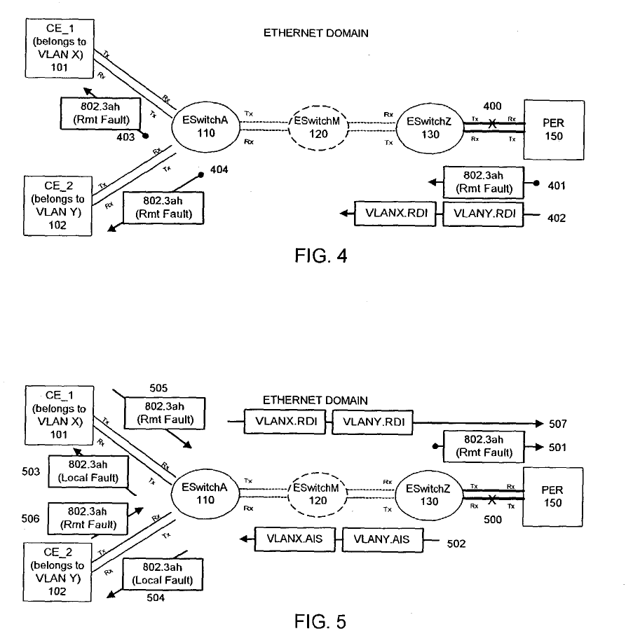

The basic principle is as follows: when a failure occurs on any link in the end-to-end path, an attempt is made to notify the end stations of the failure so that appropriate re-routing may occur. FIG. 4 through FIG. 13 illustrate the automatic failure notification mechanisms, in light of different possible interface failures that can occur in the network shown in FIG. 2.

1. Rx FAILS ON PER. FIG. 4 illustrates the situation where an Rx interface fails on the provider edge router 150. This is depicted at 400 in FIG. 4. In accordance with an embodiment of the invention, at 401, the PER 150 transmits a point-to-point failure notification, e.g. using an IEEE 802.3ah REMOTE FAULT notification as mentioned above, towards the Ethernet switch “ESwitchZ” 130. This notification covers only the link to ESwitchZ 130. The PER 150 also takes all VLAN sub-interfaces out of service on this link. At 402, the PER 150 transmits a VLAN Remote Defect Indicator (RDI), as described above, on all VLANs on that physical link (in this example, these are VLAN “X” and “Y”) back towards the customer routers 101, 102. The Ethernet domain switches the packets based on their VLAN tags and eventually forwards the RDI messages to “ESwitchA” 110. Since the links to the routers are untagged, the RDI message would need to be transmitted to the routers 101, 102 using an 802.3ah notification in a standard Ethernet 11 PDU (not utilizing VLAN tags). In this case, the Ethernet switch ESwitchA 110 at 403 and 404 sends an OAM packet to the routers 101, 102 respectively that indicates there is a remote failure. If configured properly, the routers 101, 102 would receive the failure notice, take that particular route out of service, and re-route traffic over a secondary path.

2. Rx FAILS ON ESwitchZ (FACING PER). FIG. 5 illustrates the situation where an Rx interface fails on the Ethernet switch “ESwitchZ” 130 facing the provider edge router 150. This is depicted at 500 in FIG. 5. In accordance with an embodiment of the invention, at 501, the ESwitchZ 130 transmits a point-to-point failure notification using 802.3ah towards the PER 150. This notification only covers the link to the PER 150. The PER 150 proceeds to take all sub-interfaces out of service on this link. At 502, ESwitchZ 130 transmits a VLAN Alarm Indication Signal (AIS), as described above, on all VLANs on that physical link (in this example, these are VLAN “X” and “Y”) back towards the customer routers 101, 102. The Ethernet domain switches the packets based on their VLAN tags and eventually forwards the AIS messages to “ESwitchA” 110. Since the links to the routers are untagged, the AIS message would need to be transmitted to the routers 101, 102 using an 802.3ah notification in a standard Ethernet 11 PDU (not utilizing VLAN tags). In this case, the Ethernet switch ESwitchA 110, at 503 and 504, sends an OAM packet to the routers 101, 102 respectively that indicates there is a local fault. If configured properly, the routers 101, 102 would receive the failure notice, take that particular route out of service, and re-route traffic over a secondary path. Additionally, the routers 101, 102 would, at 505, 506, transmit an 802.3ah PDU indicating a REMOTE FAULT back towards ESwitchA 110. ESwitchA 110 would then create VLAN RDI PDUs and forward them to the PER 150 at 507. Normally, the PER 150 would receive the VLAN RDIs and take the specific sub-interfaces out of service. In this case, however, the PER 150 already took the sub-interfaces out of service because of the earlier notification.

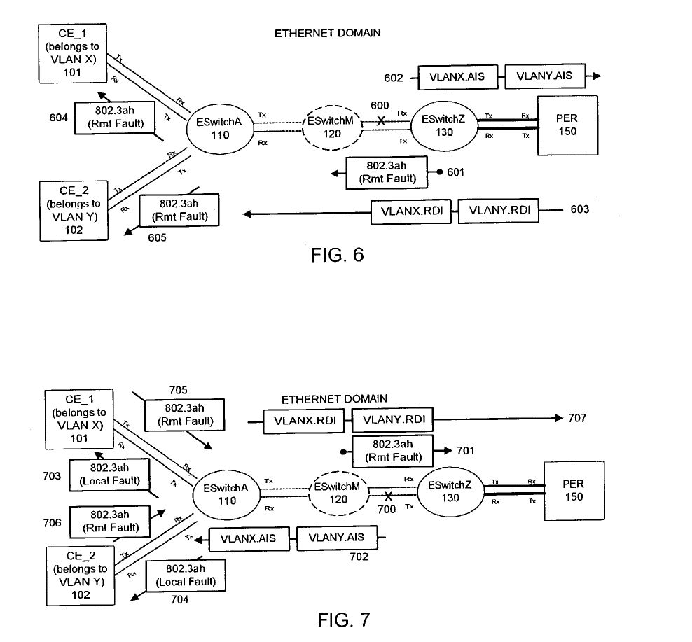

3. Rx FAILS ON ESwitchZ (FACING ESwitchM). FIG. 6 illustrates the situation where an Rx interface fails on the Ethernet switch “ESwitchZ” 130 facing “ESwitchM” 120. This is depicted at 600 in FIG. 6. In accordance with an embodiment of the invention, at 601, ESwitchZ 130 transmits a point-to-point failure notification using 802.3ah towards the core of the Ethernet domain, i.e. ESwitchM 120. This notification covers only the link to ESwitchM 120. At 602, the ESwitchZ 130 sends a VLAN AIS notification towards the PER 150 for all VLANs configured on the failed interface. The PER 150 receives the VLAN AIS packets, e.g. for VLAN X,Y, and takes those sub-interfaces out of service. At 603, the PER 150 then transmits a VLAN RDI on the VLANs (i.e. VLAN X,Y) towards both customer routers 101, 102. The Ethernet domain switches the packets based on their VLAN tags and eventually forwards the RDI messages to “ESwitchA” 110. Since the links to the routers are untagged, the RDI message would need to be transmitted to the routers 101, 102 using an 802.3ah notification in a standard Ethernet II PDU (not utilizing VLAN tags). In this case, the Ethernet switch ESwitchA 110 at 604 and 605 sends an OAM packet to the routers 101, 102 respectively that indicates there is a remote failure. If configured properly, the routers 101, 102 would receive the failure notice, take that particular route out of service, and re-route traffic over a secondary path.

4. Rx FAILS ON ESwitchM (FACINC ESwitchZ). FIG. 7 illustrates the situation where an Rx interface fails on the Ethernet switch “ESwitchM” 120 facing “ESwitchZ” 130. This is depicted at 700 in FIG. 7. In accordance with an embodiment of the invention, at 701, the ESwitchM 120 transmits a point-to-point failure notification using 802.3ah towards the ESwitchZ 130. This notification only covers the link to ESwitchZ 130. At 702, ESwitchM 120 transmits a VLAN AIS towards the customer routers 101, 102. The Ethernet domain switches the packets based on their VLAN tags and eventually forwards the AIS messages to “ESwitchA” 110. Since the links to the routers are untagged, the AIS message would need to be transmitted to the routers 101, 102 using an 802.3ah notification in a standard Ethernet II PDU (not utilizing VLAN tags). In this case, the Ethernet switch ESwitchA 110, at 703 and 704, sends an OAM packet to the routers 101, 102 respectively that indicates there is a local fault. If configured properly, the routers 101, 102 would receive the failure notice, take that particular route out of service, and re-route traffic over a secondary path. Additionally, the routers 101,102 would, at 705, 706, transmit an 802.3ah PDU indicating a REMOTE FAULT back towards ESwitchA 110. ESwitchA 110 would then create VLAN RDI PDUs and forward them to the PER 150 at 707. The PER 150 would receive the VLAN RDIs and proceeds to take the specific sub-interfaces out of service.

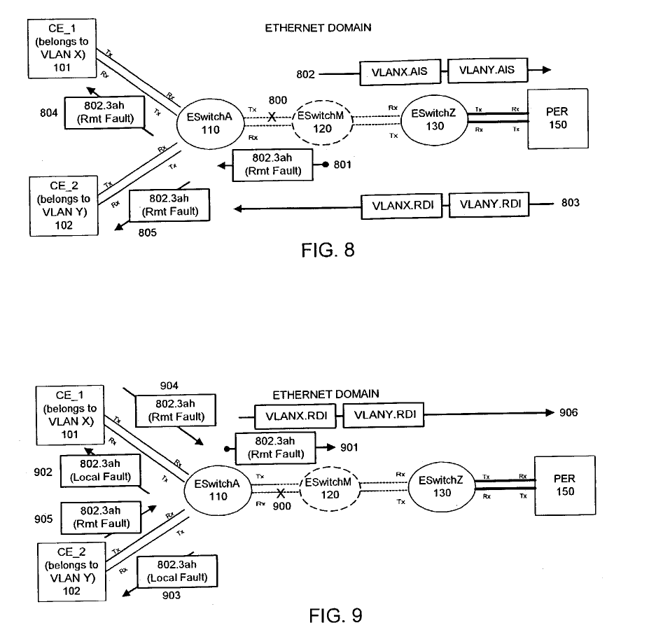

5. Rx FAILS ON ESwitchM (FACING ESwitchA). FIG. 8 illustrates the situation where an Rx interface fails on the Ethernet switch “ESwitchM” 120 facing “ESwitchA” 110. This is depicted at 800 in FIG. 8. In accordance with an embodiment of the invention, at 801, ESwitchM 120 transmits a point-to-point failure notification using 802.3ah towards ESwitchA 110. This notification covers only the link to ESwitchA 110. At 802, the ESwitchM 120 sends a VLAN AIS notification towards the PER 150 for all VLANs configured on the failed interface. The PER 150 receives the VLAN AISpackets, e.g. for VLAN X,Y, and takes those sub-interfaces out of service. At 803, the PER 150 then transmits a VLAN RDI on the VLANs (i.e. VLAN X,Y) towards both customer routers 101, 102. The Ethernet domain switches the packets based on their VLAN tags and eventually forwards the RDI messages to “ESwitchA” 110. Since the links to the routers are untagged, the RDI message would need to be transmitted to the routers 101, 102 using an 802.3ah notification in a standard Ethernet II PDU (not utilizing VLAN tags). In this case, the Ethernet switch ESwitchA 110 at 804 and 805 sends an OAM packet to the routers 101 , 102 respectively that indicates there is a remote failure. If configured properly, the routers 101, 102 would receive the failure notice, take that particular route out of service, and re-route traffic over a secondary path.

6. Rx FAILS ON ESwitchA (FACING ESwitchM). FIG. 9 illustrates the situation where an Rx interface fails on the Ethernet switch “ESwitchA” 110 facing “ESwitchM” 120. This is depicted at 900 in FIG. 9. In accordance with an embodiment of the invention, at 901, ESwitchA 120 transmits a point-to-point failure notification using 802.3ah towards the ESwitchM 120. This notification only covers the link to ESwitch 120. At 902, ESwitchA 110 transmits a 802.3ah local fault message towards customer router 101; likewise, at 903, ESwitchA 110 transmits an OAM packet to customer router 102. The routers respond as described above. If configured properly, the routers 101, 102 receive the failure notice, take that particular route out of service, and re-route traffic over a secondary path. Additionally, the routers 101, 102, at 904, 905, transmit an 802.3ah PDU indicating a REMOTE FAULT back towards ESwitchA 110. ESwitchA 110 then creates VLAN RDI PDUs and forwards them to the PER 150 at 906. The PER 150 receives the VLAN RDIs and proceeds to take the specific sub-interfaces out of service.

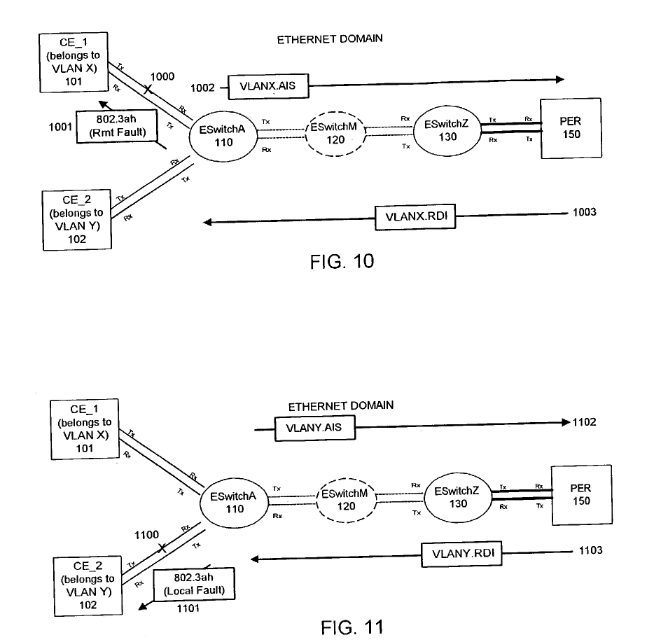

7. Rx FAILS ON ESwitchA (FACING CE1). FIG. 10 illustrates the situation where an Rx interface fails on the Ethernet switch “ESwitchA” 120 facing customer router 101. This is depicted at 1000 in FIG. 10. In accordance with an embodiment of the invention, at 1001, ESwitchA 120 transmits a failure notification using 802.3ah towards the customer router 101, denoted “CE1” in FIG. 10. If configured properly, the router 101 takes this link out of service and selects a secondary route. At 1002, the ESwitchA 110 sends a VLAN AIS notification towards the PER 150 for VLAN X only. The PER 150 receives the VLAN AIS for VLAN X and takes that sub-interface out of service. At 1003, the PER 150 then transmits a VLAN RDI for VLAN X only back towards the customer routers 101. The Ethernet domain switches the packets based on their VLAN tags and eventually forwards the RDI messages to ESwitchA 110. ESwitchA receives the VLAN-X.RDI and creates an 802.3ah remote failure PDU and forwards it to the customer router 101. Since customer router 101 took the link out of service above, no new action would occur.

8. Rx FAILS ON ESwitchA (FACING CE2). FIG. 11 illustrates the situation where an Rx interface fails on the Ethernet switch “ESwitchA” 120 facing customer router 102. This is depicted at 1100 in FIG. 11. In accordance with an embodiment of the invention, at 1101, ESwitchA 120 transmits a failure notification using 802.3ah towards the customer router 102, denoted “CE2” in FIG. 11. If configured properly, the router 102 takes this link out of service and selects a secondary route. At 1102, the ESwitchA 110 sends a VLAN AIS notification towards the PER 150 for VLAN Y only. The PER 150 receives the VLAN AIS for VLAN Y and takes that sub-interface out of service. At 1103, the PER 150 then transmits a VLAN RDI for VLAN Y only back towards the customer routers 102. The Ethernet domain switches the packets based on their VLAN tags and eventually forwards the RDI messages to ESwitchA 110. ESwitchA receives the VLAN-Y.RDI and creates an 802.3ah remote failure PDU and forwards it to the customer router 102. Since customer router 102 took the link out of service above, no new action would occur.

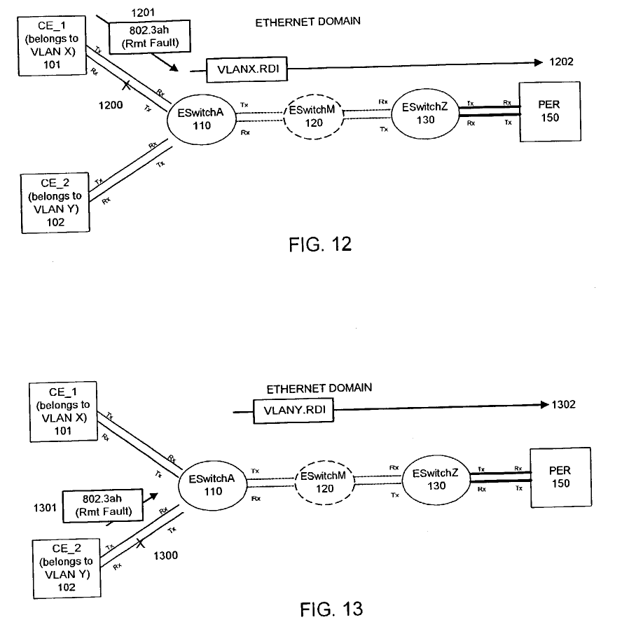

9. Rx FAILS ON CE1. FIG. 12 illustrates the situation where an Rx interface fails on customer router 101. This is depicted at 1200 in FIG. 12. In accordance with an embodiment of the invention, at 1201, the customer router 101 transmits a remote failure notification using 802.3ah towards the Ethernet switch “ESwitchA” 110. This notification only covers the link to ESwitchA 110. If configured properly, the router 101 also takes that route out of service and selects a secondary route. When ESwitchA 110 receives the failure notification, it creates a VIAN RDI PDU at 1202 and forwards it to the PER 150 for VLAN X. The PER 150 receives the VLAN RDI for VLAN X and takes that sub-interface out of service.

10. Rx FAILS ON CE2. FIG. 13 illustrates the situation where an Rx interface fails on customer router 102. This is depicted at 1300 in FIG. 13. In accordance with an embodiment of the invention, at 1301, the customer router 102 transmits a remote failure notification using 802.3ah towards the Ethernet switch “ESwitchA” 110. This notification only covers the link to ESwitchA 110. If configured properly, the router 102 also takes that route out of service and selects a secondary route. When ESwitchA 110 receives the failure notification, it creates a VLAN RDI PDU at 1302 and forwards it to the PER 150 for VLAN Y. The PER 150 receives the VLAN RDI for VLAN Y and takes that sub-interface out of service.

It should be emphasized that the invention is not limited to customer equipment with untagged links to the Ethernet domain. Although not explicitly shown in FIG. 4 though 13, the mechanisms are readily extendable to tagged customer links. Consider the customer router 103 shown in FIG. 2 with a tagged link to ESwitchA 110. In the examples shown in FIG. 4, FIG. 6 and FIG. 8, a VLAN Remote Defect Indicator message would be transmitted on VLAN Z which would directly arrive at the customer router 103 without the need to translate the message into an 802.3ah Remote Fault message. The customer router 103 would treat the VLAN Remote Defect Indicator analagously to how customer routers 101, 102 treat an 802.3ah Remote Fault message, namely by taking the particular route out of service and re-routing traffic over a secondary path.

The foregoing Detailed Description is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that various modifications may be implemented by those skilled in the art without departing from the scope and spirit of the invention. For example, the detailed description describes an embodiment of the invention with particular reference to Ethernet-based architectures. However, the principles of the present invention could be readily extended to other broadcast layer two protocols. Such an extension could be readily implemented by one of ordinary skill in the art given the above disclosure.

1. a method of failure notification in an Ethernet domain, the method comprising the steps of:
detecting a failure on a link in the Ethernet domain;
generating a virtual local area network failure notification message that is broadcast to all stations belonging to and managing traffic for a virtual local area network affected by the failure; and
where the virtual local area network failure notification message must traverse an untagged boundary of the Ethernet domain, translating the virtual local area network failure notification message into a protocol data unit that does not utilize virtual local area network tagging, thereby notifying end stations of the failure so that appropriate re-routing may occur.

2. The method of claim 1 further comprising the step of utilizing a point-to-point failure notification message to alert local Ethernet nodes of the failure.

3. The method of claim 2 wherein the virtual local area network failure notification message is an alarm indication signal message or a remote defect indicator message.

4. The method of claim 3 wherein a remote defect indicator message is generated at an end station if an alarm indication signal message is received.

5. The method of claim 4 wherein the end stations are layer three routers.
